(19) United States
(12) Patent Application Publication
(10) Pub. No.: US 2008/0090399 A1
(43) Pub. Date: Apr. 17, 2008

(54) ELECTRODE FOR IMPLANTABLE DEVICE

(76) Inventors: Shamim M. Malik, Temecula, CA (US); Piotr Waszczuk, St. Paul, MN (US); Daniel J. Cooke, Roseville, MN (US)

Correspondence Address: SCHWEGMAN, LUNDBERG & WOESSNER, P.A., P.O. BOX 2938, MINNEAPOLIS, MN, 55402, US

(21) Appl. No.: 11/550,117

(22) Filed: Oct. 17, 2006

(51) Int. Cl. H01L 21/44

(52) U.S. Cl. 438/597

(57) ABSTRACT

An electrode includes a titanium substrate with a surface including an implanted layer of titanium oxy-nitride compounds.

### TECHNICAL FIELD

This invention relates to the field of medical devices, and more specifically to an electrode for an implantable device.

### BACKGROUND

Leads having electrodes implanted in or about the heart have been used to reverse certain life threatening arrhythmia, or to stimulate contraction of the heart. Electrical energy is applied to the heart via an electrode to return the heart to normal rhythm. Leads are usually positioned on or in the ventricle or the atrium and the lead terminal pins are attached to a pacemaker or defibrillator which is implanted subcutaneously. There is a need for further optimization of the performance of the electrode.

### SUMMARY

An electrode includes a titanium substrate with a surface including an implanted layer of titanium oxy-nitride compounds.

### BRIEF DESCRIPTION OF THE DRAWINGS

FIG. 1 shows a lead and pulse generator in accordance with one embodiment.

FIG. 2 shows a helix electrode in accordance with one embodiment.

FIG. 3 shows a portion of an electrode in accordance with one embodiment.

FIG. 4 depicts a method of forming an electrode in accordance with one embodiment.

FIG. 5 shows a portion of a surface of an electrode, in accordance with one embodiment.

FIG. 6 shows further details of the electrode of FIG. 5.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized and that structural changes may be made without departing from the scope of the present invention. Therefore, the following detailed description is not to be taken in a limiting sense, and the scope of the present invention is defined by the appended claims and their equivalents.

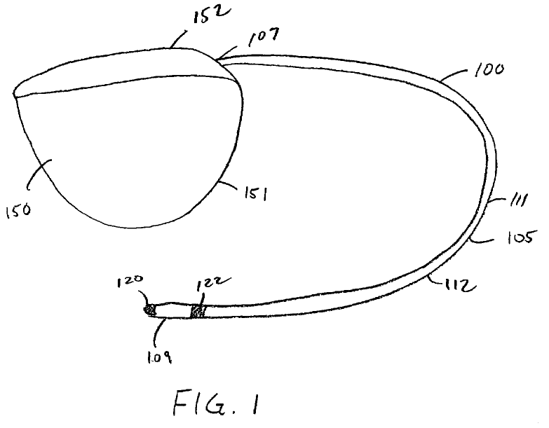

FIG. 1 shows a view of a lead 100 coupled to a pulse generator 150. In one embodiment, lead 100 is adapted to deliver pacing energy to a heart. Certain embodiments deliver defibrillation shocks to a heart. Pulse generator 150 can be implanted in a surgically-formed pocket in a patient's chest or other desired location. Pulse generator 150 generally includes electronic components to perform signal analysis, processing, and control. Pulse generator 150 can include a power supply such as a battery, a capacitor, and other components housed in a case or can 151. The device can include microprocessors to provide processing and evaluation to determine and deliver electrical shocks and pulses of different energy levels and timing for ventricular defibrillation, cardioversion, and pacing to a heart in response to cardiac arrhythmia including fibrillation, tachycardia, and bradycardia.

In one embodiment, lead 100 includes a lead body 105 extending from a proximal end 107 to a distal end 109 and having an intermediate portion 111. Lead 100 includes one or more conductors, such as coiled conductors or other conductors, to conduct energy from pulse generator 150 to one or more electrodes, such as tip electrode 120 and ring electrode 122. The conductors can also receive signals from the heart to transfer back to the pulse generator. The lead further includes outer insulation 112 to insulate the conductor. Lead terminal pins are attached to pulse generator 150 at a header 152. The system can include a unipolar system with the case acting as an electrode or a bipolar system with a pulse between two distally located electrodes, such as tip electrode 120 and ring electrode 122, for example.

As will be further discussed below, in one embodiment electrode 120 and/or electrode 122 can include an electrode body formed of a titanium substrate having a titanium oxy-nitride compound layer outer surface. In certain embodiments, the titanium oxy-nitride compound layer outer surface is an implanted layer formed by plasma ion implantation. In some examples, pulse generator can 150 can be used as an electrode and include a titanium oxy-nitride compound layer, as disclosed herein. In some embodiments, electrode 120 and/or electrode 122 can include a titanium coated substrate.

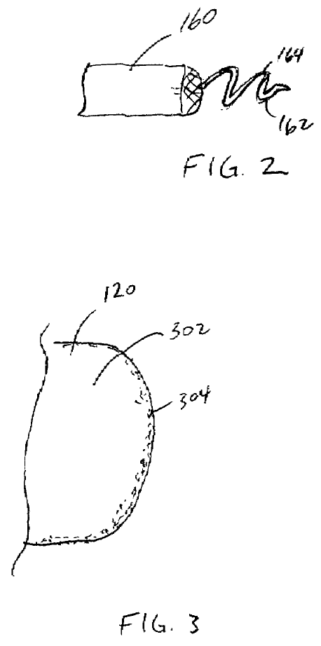

FIG. 2 shows an example of a distal portion of a lead 160 having a helix 162. In one embodiment, helix 162 can be electrically active and can be used to screw into the myocardium to actively fixate the electrode to the heart. As will be discussed below, helix 162 can include a titanium substrate and include an outer surface 164 including titanium oxy-nitride compounds.

FIG. 3 shows a portion of electrode 120. The following discussion applies to all the electrodes discussed above or below. Electrode 120 includes a titanium substrate 302 and at or near a surface of the electrode an implanted layer of titanium oxy-nitride compounds 304 is formed.

Titanium oxy-nitride compounds 304 are electrical insulators. Accordingly, an electrode 120 formed this way will function as a capacitive stimulation electrode and/or sensing (recording) electrode. Such an electrode is stable in vitro, and is capable of conducting AC at high current densities, but at the same time poses infinite (or very high) resistance to DC leakage. This way, the electrodes discussed herein are able to serve as stimulation and sensing electrodes, since the stimulation and sensing currents are AC in nature. At the same time the electrodes will minimize the contribution of irreversible faradaic processes to the charge injection process, since the electrodes have an extremely high impedance to the DC charge transfer through the insulation layer. In certain embodiments, the electrode layer of titanium oxy-nitride compounds 304 can also serve as a substrate for development of further layers of coatings that will improve biocompatibility of the electrode and can serve as drug delivery vehicles.

In certain embodiments, the present system can help overcome the formation of thick scar tissue around the stimulation site which can result in a high pacing threshold. The capacitive stimulation of electrode 120 has advantage over stimulation involving DC currents because, during direct stimulation, the irreversible faradaic electrochemical processes employed for DC charge injection can be detrimental to the stimulated tissue and lead to increase of the scar tissue around the electrode and, consequently to increase in pacing threshold.

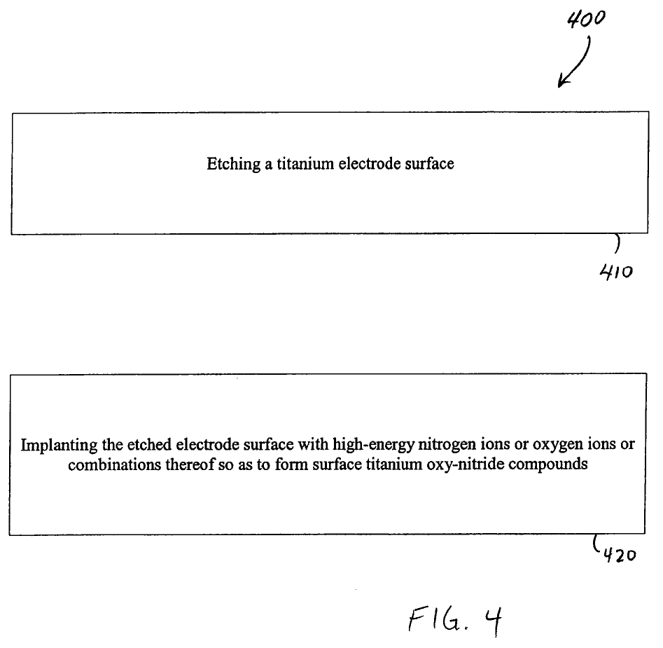

FIG. 4 depicts a method of forming an electrode, in accordance with one embodiment. Method 400 includes etching a titanium electrode surface (410); and implanting the etched electrode surface with high-energy nitrogen ions or oxygen ions or combinations thereof so as to form surface titanium oxy-nitride compounds (420).

In one embodiment, etching the electrode surface can include etching with low energy argon, krypton, or CF4 ions. This increases the surface area of the electrode. In one embodiment, etching can include chemically etching the surface with exalic acid, for example.

In one embodiment, implanting the etched electrode surface includes a plasma immersion ion implantation process as follows: The etched electrodes can be loaded into an ion bombardment chamber. The chamber is evacuated and argon plasma is used to pre-clean the electrode surface at 10 kV pulses applied to the electrode. In one example, an oxygen and nitrogen mixture plasma is generated using RF 13.56 MHz. 30 kV pulses are applied to the electrodes to do the plasma ion implantation. In certain embodiments, the ions are positively charged and the electrode surface is negatively biased. This plasma ion implantation process can include a non-line-of-sight process and thus odd shapes can be treated with good conformality and uniformity. During the plasma ion implantation process the accelerated ions impinge on the substrate surface with high kinetic energy and incident ions impart energy to substrate atoms via collisions until they are stationary. In certain embodiments, some ions can be buried up to about 800 Angstroms or less under the substrate surface. In some embodiments, some ions can be buried up to about 2000 Angstroms or less under the substrate surface. In certain embodiments, the plasma ion implantation process discussed above results in co-ion implantation of oxygen and nitrogen simultaneously. The simultaneous implantation of the oxygen and nitrogen ions of the plasma results in the titanium-oxy-nitride layer over the electrode substrate.

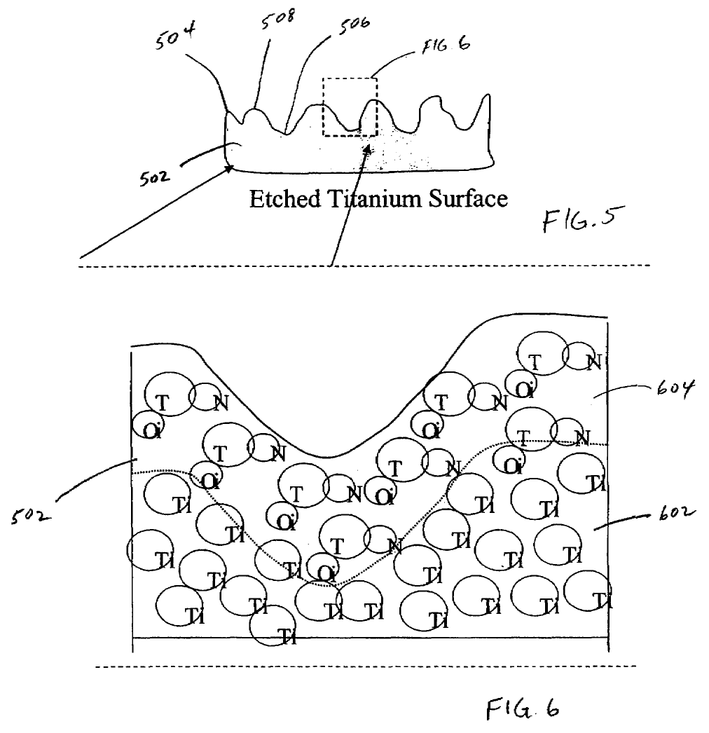

FIG. 5 shows a portion of a surface 504 of an electrode 502, showing a number of valleys 506 and peaks 508 and FIG. 6 shows further details of the electrode 502 surface. During the plasma ion implantation process discussed above, accelerated nitrogen and oxygen ions impinge on the titanium substrate material 602 with high kinetic energy. As discussed, incident ions impart energy to substrate atoms via collisions until the incident ions are stationary and some of the ions can be buried at least up to about 800 Angstroms under the material surface. The ions are implanted until a surface layer 604 is formed including titanium oxy-nitride compounds (T-Oi-N). In one embodiment, the ion implantation process retains surface morphology without filling the valleys so that the implanted layer has a similar morphology as the etched surface. In some examples, the process can fill the valleys.

As discussed above, the isolative properties of the materials create a capacitive electrode/tissue interface. Pacing through such an interface leads to elimination of production of byproduct toxins that are known to degrade pacing performance of conventional pacing electrodes.

Moreover, the present system improves the electrical performance of pacing/sensing electrodes. When compared to current electrodes, the present electrodes can have higher capacitance and lower sensing impedance.

Electrode capacitance is directly proportional to charge storage capacity (mC/cm²). Applying the titanium oxy-nitride layer to titanium electrodes by one embodiment of the present process can increase its capacitance by 30 to 40 times when measured by cyclic voltammetry (CV) or electrochemical impedance spectroscopy (EIS). This significantly increases the electrode charge storage capacity and allows for safe deliveries of charge densities that are much greater than those achieved with previous electrodes.

Sensing impedance is inversely proportional to electrode surface area. Smaller electrodes are being developed as a result of diminishing lead body size and in an effort to increase pacing impedance. Therefore, the sensing impedance is rising because the electrode surface area is dropping.

In various embodiments, the electrode surface processing described above can be applied to electrodes including a helix, a tip electrode, a ring electrode, and a defibrillation coil electrode. In various embodiments, the present system includes a surface modification of pacing/sensing electrodes for pacing, defibrillation, and HF leads.

It is understood that the above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

What is claimed is:

1. An electrode comprising:
a titanium substrate; and
a surface of the titanium substrate including a layer of implanted titanium oxy-nitride compounds.

2. The electrode of claim 1, wherein the titanium substrate is formed as a tip electrode for an implantable lead.

3. The electrode of claim 1, wherein the titanium substrate is formed as a ring electrode for an implantable lead.

4. The electrode of claim 1, wherein the electrode includes a helix.

5. The electrode of claim 1, wherein the titanium substrate includes an etched outer surface.

6. The electrode of claim 5, wherein the layer of titanium oxy-nitride compounds includes a similar morphology as the etched outer surface of the titanium substrate.

7. A lead comprising:
a lead body extending from a proximal end to a distal end; and
an electrode disposed along the lead body and including a substrate including titanium with a surface of the substrate including an implanted layer of titanium oxy-nitride compounds.

8. The electrode of claim 7, wherein the substrate includes a titanium substrate.

9. The electrode of claim 7, wherein the substrate includes a titanium coated substrate.

10. The electrode of claim 7, wherein the electrode includes a tip electrode, a ring electrode, or a helix.

11. The electrode of claim 7, wherein the substrate includes an etched outer surface.

12. The electrode of claim 11, wherein the layer of titanium oxy-nitride compounds includes a similar morphology as the etched outer surface of the substrate.

13. A method comprising:
etching a titanium electrode surface; and
forming surface oxy-nitride compounds along the titanium electrode surface, including implanting at least one of high-energy nitrogen ions or high-energy oxygen ions within the etched electrode surface.

14. The method of claim 13, wherein etching includes etching with low energy ions.

15. The method of claim 13, wherein implanting includes using a plasma ion implantation process.

16. The method of claim 13, wherein implanting includes implanting until a surface layer is formed including titanium oxy-nitride compounds at least about 800 Angstroms below the electrode surface.

17. The method of claim 13, wherein implanting includes delivering both high-energy nitrogen ions and oxygen ions.

18. The method of claim 13, wherein implanting includes forming a titanium oxy-nitride compound layer having a similar morphology as the etched outer surface of the etched titanium electrode.

19. The method of claim 13, wherein etching includes etching a helix electrode surface.

20. The method of claim 13, wherein etching includes etching a pacing electrode surface.
